(19) United States
(12) Patent Application Publication
(10) Pub. No.: US 2023/0063982 A1
(43) Pub. Date: Mar. 2, 2023

(54) SEMICONDUCTOR LASER DIODE AND METHOD FOR PRODUCING A SEMICONDUCTOR LASER DIODE

(71) Applicant: OSRAM Opto Semiconductors GmbH, Regensburg (DE)

(72) Inventor: Jens Ebbecke, Rohr In Niederbayern (DE)

(73) Assignee: OSRAM Opto Semiconductors GmbH, Regensburg (DE)

(21) Appl. No.: 17/792,991

(22) PCT Filed: Jan. 12, 2021
(86) PCT No.: PCT/EP2021/050478

§ 371 Date: Jul. 14, 2022

(30) Foreign Application Priority Data
Jan. 16, 2020 (DE) 10 2020 200 468.4

(51) Int. Cl. H01S 5/20

(52) U.S. Cl. CPC H01S 5/2068; H01S 5/2072

(57) ABSTRACT

The semiconductor laser diode includes a semiconductor layer sequence having an active zone. The semiconductor layer sequence has a shape of a generalized cylinder or a frustum, and a main axis of the semiconductor layer sequence is perpendicular to a main extension plane of the semiconductor layer sequence. The semiconductor layer sequence has a core region and an edge region directly adjacent to the core region. The main axis passes through the core region. The edge region borders the core region in directions perpendicular to the main axis. The semiconductor layer sequence has a larger refractive index in the core region than in the edge region.

### CROSS-REFERENCE TO RELATED APPLICATIONS

This patent application is a national stage entry from International Application No. PCT/EP2021/050478, filed on Jan. 12, 2021, published as International Publication No. WO 2021/144261 A1 on Jul. 22, 2021, and claims priority under 35 U.S.C. § 119 from German patent application 10 2020 200 468.4, filed Jan. 16, 2020, the entire contents of all of which are incorporated by reference herein.

### FIELD

A semiconductor laser diode is specified. In addition, a method for producing a semiconductor laser diode is specified.

### BACKGROUND

An object to be solved is, inter alia, to specify a semiconductor laser diode characterized by lower cost, longer life, and easier handling. Another object to be solved is, inter alia, to specify a method for producing such a semiconductor laser diode.

These tasks are solved by a device with the features of independent patent claim 1 and by a method with the features of independent patent claim 13, respectively. Advantageous embodiments and further developments are the subject of the respective dependent patent claims.

### SUMMARY

According to at least one embodiment of the semiconductor laser diode, the latter comprises a semiconductor layer sequence with an active zone. For example, the semiconductor layer sequence comprises a p-type semiconductor layer and an n-type semiconductor layer, wherein the active zone is arranged between the p-type layer and the n-type layer. The active zone is configured to generate electromagnetic radiation. In particular, the active zone comprises at least one quantum well structure in the form of a single quantum well, short SQW, or in the form of a multi-quantum well structure, short MQW. Additionally, the active zone may comprise one, preferably more, secondary well structures. For example, electromagnetic radiation in the blue or green or red spectral range or in the UV range or in the IR range is generated in the active zone during intended operation. In particular, it is possible that electromagnetic radiation in a wavelength range between including the IR region and including the UV region is generated in the active zone.

For example, the semiconductor layer sequence is based on a nitride compound semiconductor material, such as AlₙIn₁₋ₙ₋ₘGaₘN, or on a phosphide compound semiconductor material, such as AlnIn1-n-mGamP, or on an arsenide compound semiconductor material, such as AlₙIn₁₋ₙ₋ₘGaₘAs, wherein 0≤n≤1, 0≤m≤1, and m+n≤1, respectively. The semiconductor layer sequence may comprise dopants as well as additional components. For simplicity, however, only the essential constituents of the crystal lattice of the semiconductor layer sequence, i.e. Al, As, Ga, In, N or P, are specified, even if these may be partially replaced and/or supplemented by small amounts of further substances.

According to at least one embodiment of the semiconductor laser diode or its embodiment described above, the semiconductor layer sequence comprises a shape of a generalized cylinder or a frustum with a main axis, which is perpendicular to a main extension plane of the semiconductor layer sequence. In particular, the main axis is perpendicular to a main extension plane of the active zone.

Preferably, the semiconductor layer sequence comprises the geometric shape of a straight circular cylinder. For example, the semiconductor layer sequence is then circular in plan view. In particular, the main axis is then a rotational symmetry axis of the semiconductor layer sequence. By “straight circular cylinder” is meant here and in the following a cylindrical geometric figure which comprises a circular disk as base surface and cover surface, respectively, and a lateral surface connecting the base surface with the cover surface. In particular, the base surface and the top surface are congruent when viewed perpendicular to one of the two surfaces. Here and in the following, “plan view” means a view of the semiconductor layer sequence in the direction of the main axis.

Alternatively, the semiconductor layer sequence comprises, for example, the geometric shape of a prism, in particular a straight prism. In particular, a base surface of the prism can be seen in plan view. For example, in plan view, the semiconductor layer sequence comprises the shape of a polygon, in particular that of a hexagon or an octagon. Here and hereinafter, “prism” refers to a geometric figure comprising a polygon as a base surface and a top surface. Further, the prism comprises a lateral surface connecting the base surface with the top surface. In the case of “a straight prism”, the base surface and the cover surface are congruent in view perpendicular to one of the two surfaces.

In addition, it is possible for the semiconductor layer sequence to comprise a shape of a frustum. For example, the main axis is a rotational symmetry axis of the semiconductor layer sequence. A main surface of the semiconductor layer sequence comprises, for example, a circular disk shape in plan view. A base surface of the semiconductor layer sequence opposite to the main surface comprises, for example, a circular disk shape in plan view. The base surface and the main surface are parallel to the main extension plane of the semiconductor layer sequence and, in particular, perpendicular to the main axis. Preferably, the base surface comprises a smaller radius than the main surface. Thus, a side surface, also called lateral surface, of the semiconductor layer sequence includes an angle with the main surface. This angle is in particular between 30° and 60° inclusive, for example 45°.

In plan view, the semiconductor layer sequence comprises, for example, a diameter, measured perpendicular to the main axis, of at least 1 μm and at most 500 μm, in particular of at least 5 μm and at most 50 μm. A thickness of the semiconductor layer sequence, measured parallel to the main axis, is for example at most 20 μm, preferably between 2 μm and 5 μm inclusive. Radiation which is generated in the active zone during intended operation leaves the semiconductor laser diode, for example, transversely, in particular perpendicularly, to the main axis.

According to at least one embodiment of the semiconductor laser diode or its embodiments described above, the semiconductor layer sequence comprises a core region and an edge region directly adjacent to the core region. The main axis passes through the core region. The edge region bounds the core region in directions perpendicular to the main axis. For example, the edge region bounds the core region in all directions perpendicular to the main axis. For example, the core region comprises the same geometric shape as the semiconductor layer sequence. For example, the core region comprises the shape of a straight circular cylinder or the shape of a prism.

In particular, in the case where the semiconductor layer sequence comprises the shape of a frustum, the core region has the shape of a straight circular cylinder.

For example, in plan view of the semiconductor layer sequence, the core region comprises the shape of a circular disk within a manufacturing tolerance. For example, the manufacturing tolerance allows deviations of at most 10% or at most 5%. Preferably, the core region comprises an axis of rotational symmetry which is parallel to the main axis of the semiconductor layer sequence. Further preferably, the rotational symmetry axis of the core region coincides with the main axis of the semiconductor layer sequence. For example, the core region comprises a diameter, measured perpendicular to the rotational symmetry axis, of at least 1 μm and of at most 500 μm, in particular of at least 5 μm and 50 μm. The thickness of the core region, measured parallel to the axis of rotational symmetry, preferably coincides with the thickness of the semiconductor layer sequence.

The edge region comprises, for example, the shape of a circular ring in plan view of the semiconductor layer sequence from the direction of the main axis within the manufacturing tolerance. The edge region can thus preferably be identified in plan view by two concentric circular lines and an area between the circular lines. In particular, the edge region then comprises the shape of a hollow cylinder. In a direction parallel to the main axis, the edge region preferably comprises a thickness which coincides with the thickness of the core region and/or the thickness of the semiconductor layer sequence. For example, the circular ring to be seen in plan view comprises a width resulting from the difference of the diameters of the concentric circles, which is between 100 nm and 10 μm. Preferably, the width is at least 1 μm and at most 2 μm. In particular, the edge region also comprises an axis of rotational symmetry. Preferably, the rotational symmetry axis of the edge region is parallel to the rotational symmetry axis of the core region or to the main axis of the semiconductor layer sequence. Further preferably, the symmetry axes of the edge region and the core region coincide with the main axis of the semiconductor layer sequence.

In particular, in the case where the semiconductor layer sequence comprises the shape of a frustum, the width of the edge region decreases starting from the main surface of the semiconductor layer sequence in the direction of the base surface of the semiconductor layer sequence.

According to at least one embodiment of the semiconductor laser diode or its embodiments described above, the semiconductor layer sequence comprises a larger refractive index in the core region than in the edge region. For example, the difference in refractive index is at least 0.1% and at most 1%. For example, the difference in refractive index is 1×10⁻³.

For example, the refractive index at an interface between the core region and the edge region changes over a distance of at most 200 nm, preferably of at most 100 nm.

In at least one embodiment, the semiconductor laser diode comprises a semiconductor layer sequence with an active zone. The semiconductor layer sequence comprises the shape of a generalized cylinder, and a main axis of the semiconductor layer sequence is perpendicular to a main extension plane of the semiconductor layer sequence. The semiconductor layer sequence comprises a core region and an edge region directly adjacent to the core region. The main axis passes through the core region. The edge region bounds the core region in directions perpendicular to the main axis. The semiconductor layer sequence in the core region comprises a larger refractive index than in the edge region.

A semiconductor laser diode described here is based inter alia on the following technical ideas. In order to realize a particularly small laser diode, it may be designed cylindrically or in the form of a prism with a polygon as base surface. In such a semiconductor laser diode, so-called ring modes, also known as whispering gallery modes, are generated. These modes run along an outer surface of the laser diode, whereby a surface treatment of the outer surface has considerable influence on the efficiency and radiation characteristics of the laser diode.

In conventional semiconductor laser diodes, especially infrared laser diodes, for example, the outside is cleaned with a hydrogen plasma and subsequently passivated. The passivation is carried out, for example, with ZnSe or a similar material. This method is mostly performed by molecular beam epitaxy (MBE). However, MBE represents a complex and cost-intensive process.

The semiconductor laser diode described here makes use, inter alia, of the idea of changing the refractive index of the semiconductor layer sequence in an edge region in such a way that the ring mode propagates along an interface between a core region and the edge region. In the edge region, the semiconductor layer sequence has a lower refractive index than in the core region. This results in total internal reflection at the interface, whereby radiation is not guided along an outer surface of the semiconductor laser diode, but within the semiconductor layer sequence. Advantageously, this means that there is no need for time-consuming cleaning of the outside and subsequent passivation. Instead, it is possible for the outside to receive only a simple passivation layer. Thus, the influence of the outer side and consequently, for example, its contamination on the radiation characteristics and efficiency of the semiconductor laser diode can be reduced and the semiconductor laser diode can be manufactured at a lower cost.

According to at least one embodiment of the semiconductor laser diode or one of its embodiments described above, the core region and the edge region are based on the same semiconductor material system. For example, the semiconductor layer sequence in both the edge region and the core region is based on the same compound semiconductor material. In particular, the semiconductor layer sequence in the core region and the edge region has been produced in a common growth process. For example, the semiconductor layer sequence in the edge region differs from the semiconductor layer sequence in the core region with respect to its doping or its concentration of impurity atoms. In particular, the edge region has not been subsequently applied to the core region, but these two regions have been epitaxially grown substantially simultaneously, and at least one of them has been transformed into the edge region and the core region, respectively, after the growing process. In particular, the semiconductor layer sequence is formed in one piece.

According to at least one embodiment of the semiconductor laser diode or one of its embodiments described above, impurity atoms are introduced in the semiconductor layer sequence in the edge region. For example, if the material of the semiconductor layer sequence is a III-V compound semiconductor material, atoms of the second main group are introduced in the edge region. In particular, aluminum is introduced in the edge region. For example, impurity atoms are introduced in the edge region with a concentration between 1×10¹⁷ and 1×10²⁰ cm⁻³, inclusive.

In particular, introducing the impurity atoms changes the band gap of the semiconductor layer sequence within the edge region. In particular, the band gap is increased. As a consequence, the refractive index of the semiconductor layer sequence in the edge region decreases. Advantageously, the refractive index of the edge region may be selectively reduced by introducing impurity atoms in the edge region.

According to at least one embodiment of the semiconductor laser diode or one of its embodiments described above, the semiconductor layer sequence comprises the shape of a straight circular cylinder. The semiconductor layer sequence is preferably rotationally symmetrical with respect to the main axis. In particular, the main axis of the semiconductor layer sequence is an axis of rotational symmetry. Preferably, particularly compact semiconductor laser diodes may be realized with such cylindrical semiconductor layer sequences.

According to at least one embodiment of the semiconductor laser diode or one of its embodiments described above, with the exception of the embodiment described last, the semiconductor layer sequence comprises the shape of a prism. Preferably, the semiconductor layer sequence comprises the shape of a straight prism. In particular, a base surface of the prism, which can be seen in a plan view of the semiconductor layer sequence, comprises the shape of a regular polygon with at least six corners. For example, the base surface comprises the shape of a hexagon or an octagon. Advantageously, a semiconductor laser diode with the geometric shape of a prism can be produced particularly easily and at low costs.

According to at least one embodiment of the semiconductor laser diode or one of its embodiments described above, the semiconductor layer sequence comprises a central zone. The central zone is at least partially located within the edge region. The central zone includes the active zone, a first waveguide layer, and a second waveguide layer. The active zone is arranged between the first and second waveguide layers. Impurity atoms are introduced into regions of the central zone that are within the edge region. For example, the waveguide layers each comprise a dopant. For example, the first waveguide layer is n-doped and the second waveguide layer is p-doped. Alternatively, the doping can be the other way around. In particular, radiation generated in the active zone is guided in the central zone. Preferably, radiation generated in the active zone propagates in the semiconductor layer sequence only in the central zone. Advantageously, by introducing impurity atoms into the central zone, the refractive index of the central zone in the edge region may be reduced relative to the refractive index in the core region. Thus, an ring mode propagating in the central zone may be guided along an interface between the edge region and the core region.

According to at least one embodiment of the semiconductor laser diode or one of its embodiments described above, the semiconductor layer sequence comprises a main surface on which a dielectric element is arranged. The dielectric element thereby covers the core region in places. The edge region of the semiconductor layer sequence is free of the dielectric element. The dielectric element comprises a dielectric. The dielectric of the dielectric element is for example an oxide, in particular silicon dioxide (SiO2), or a nitride, such as silicon nitride (SiN). The dielectric element may also completely cover the core region. The main surface of the semiconductor layer sequence is preferably formed by an outwardly exposed surface of the semiconductor layer sequence, which is parallel to the main extension plane of the semiconductor layer sequence.

In particular, the dielectric element causes mechanical strains in the semiconductor layer sequence, which changes the refractive index of the semiconductor layer sequence. In particular, the refractive index of the semiconductor layer sequence is increased in the regions where a dielectric element is applied compared to the regions that are free of the dielectric element. The mechanical strains extend in the semiconductor layer sequence starting from the main surface of the semiconductor layer sequence. For example, the mechanical strains extend into the semiconductor layer sequence in a direction parallel to the main axis of the semiconductor layer sequence up to at most 20 μm. If a thickness of the semiconductor layer sequence measured parallel to the main axis of the semiconductor layer sequence is, for example, at most 5 μm, the mechanical strains extend in the entire semiconductor layer sequence. Advantageously, the refractive index in the core region may be selectively increased by applying a dielectric element. Thus, by applying a dielectric element, a ring mode propagating in the semiconductor layer sequence can be performed along an interface between the core region and the edge region.

According to at least one embodiment of the semiconductor laser diode or one of its embodiments described above, the dielectric element comprises a contact structure on a side facing away from the main surface of the semiconductor layer sequence. The contact structure penetrates the dielectric element in places. Further, the contact structure is in direct contact with the semiconductor layer sequence in places. In particular, the contact structure is in direct contact with the semiconductor layer sequence at the locations where it penetrates the dielectric element. For example, the dielectric element is completely covered by the contact structure when viewed from above the main surface of the semiconductor layer sequence. Preferably, the contact structure is in direct contact with the semiconductor layer sequence exclusively in the core region.

Preferably, the application of the contact structure only insignificantly changes the refractive index of the semiconductor layer sequence at the locations where the contact structure is in contact with it.

The contact structure comprises one or more metals or a mixture of metals. The metals are, for example, titanium, platinum, and gold.

In particular, in intended operation, the semiconductor layer sequence is supplied with current by means of the contact structure. Preferably, current is implied only in the core region of the semiconductor layer sequence. Preferably, electromagnetic radiation is generated only in the core region of the semiconductor layer sequence. Advantageously, a large part of the electromagnetic radiation, in particular all electromagnetic radiation generated in the active zone during intended operation, can thus propagate at an interface between the core region and the edge region.

According to at least one embodiment of the semiconductor laser diode or one of its embodiments described above, the edge region comprises an output coupling structure. The semiconductor layer sequence comprises a higher refractive index in the region of the output coupling structure than in the edge region surrounding the output coupling structure. For example, the refractive index is 1×10⁻³ higher in the region of the output coupling structure than in the edge region of the semiconductor layer sequence. In particular, the refractive index is at least 0.01% and at most 1% higher in the region of the output coupling structure of the edge region. For example, the refractive index of the semiconductor layer sequence in the region of the output coupling structure has the same value as the refractive index in the core region.

For example, no impurity atoms are introduced into the semiconductor layer sequence in the region of the output coupling structure. Advantageously, for an interface between the core region and the edge region in the region of the output coupling structure, the condition for total internal reflection is not fulfilled and radiation propagating within the core region can leave the semiconductor layer sequence in the region of the output coupling structure. Further advantageously, the geometrical shape of the semiconductor layer sequence in the region of the output coupling structure does not have to be deviated from for this purpose.

According to at least one embodiment of the semiconductor laser diode or one of its embodiments described above, a main emission direction of radiation generated in the active zone during operation is parallel to the main axis of the semiconductor layer sequence. In particular, the main emission direction is the direction in which the radiation emitted by the semiconductor laser diode during operation comprises its intensity maximum.

In this embodiment, the semiconductor laser diode comprises in particular the shape of a frustum. A side surface encloses an angle of 45° with the main surface of the semiconductor layer sequence, for example. In the region of the output coupling structure, the radiation guided in the core region during operation impinges on a side surface of the semiconductor layer sequence, since in the region of the output coupling structure the radiation penetrates into the edge region. Total internal reflection of the radiation takes place at the side surface of the semiconductor layer sequence. The radiation is preferably reflected in the direction of the main surface. Radiation then exits the semiconductor laser diode through an output coupling surface, which is formed in particular by a surface of the output coupling structure parallel to the main surface. The output coupling surface is preferably a part of the main surface.

Advantageously, physical properties of the output coupling surface may be defined in a relatively simple manner. By this is meant that in particular a reflectivity of the output coupling surface can be specified particularly well and/or non-radiating surface states can be reduced. Non-radiating surface states can lead, inter alia, to destruction of the output coupling surface, also known as “catastrophic optical mirror damage”, or COMD for short.

An adjustment of the physical properties of the output coupling surface is possible in a relatively simple way, since the output coupling surface is lithographically more accessible than the side surface. That is, a surface treatment of the output coupling surface is easier than a surface treatment of the side surface.

A semiconductor laser diode described here, whose main emission direction is perpendicular to the main extension plane of the semiconductor layer sequence, is particularly well suited for use in a display. The reason for this is in particular the possibility of making the semiconductor laser diode particularly compact.

According to at least one embodiment of the semiconductor laser diode or one of its embodiments described above, the semiconductor layer sequence is in direct contact with a further dielectric element in the region of the output coupling structure. For example, the further dielectric element comprises the same materials as the dielectric element covering the core region in places. In particular, the further dielectric element introduces mechanical strains in the semiconductor layer sequence in the region of the output coupling structure, thereby increasing the refractive index in these regions. In particular, the refractive index in the region of the output coupling structures is increased above the refractive index of the semiconductor layer sequence in the core region. Advantageously, such an increase of the refractive index in the region of the output coupling structures allows radiation propagating in the core region of the semiconductor layer sequence to be coupled out of the semiconductor layer sequence particularly efficiently.

According to at least one embodiment of the semiconductor laser diode or one of its embodiments described above, the semiconductor layer sequence is based on an AlₙIn₁₋ₙ₋ₘGaₘAs material system, AlₙIn₁₋ₙ₋ₘGaₘN material system, or AlₙIn₁₋ₙ₋ₘGaₘP material system, wherein 0≤n≤1, 0≤m≤1, and m+n≤1. Furthermore, a refractive index difference between the semiconductor layer sequence in the core region and the edge region is at least 0.1% and at most 1%. For example, the refractive index difference is at least 0.2% and at most 0.5%. For example, the semiconductor layer sequence in the core region comprises a refractive index of 3.5 and in the edge region the semiconductor layer sequence comprises a refractive index of 3.499. In particular, the refractive index is determined at a wavelength generated by the active zone in intended operation. For example, the refractive index is an average refractive index of the semiconductor layer sequence. Preferably, the refractive index is the average refractive index in the central zone of the semiconductor layer sequence. Advantageously, such a refractive index difference is sufficient for total internal reflection to occur at an interface between the edge region and the core region. Thus, a ring mode can be guided along the interface between the core region and the edge region.

A method for producing a semiconductor laser diode is further specified. In particular, the semiconductor laser diode described herein and its embodiment can be produced by the method. That is, all features disclosed for the semiconductor laser diode are also disclosed for the method, and vice versa.

According to at least one embodiment of the method, a semiconductor layer sequence with an active zone is provided. For example, the semiconductor layer sequence is provided on a substrate. For example, the substrate is a growth substrate on which the semiconductor layer sequence has been epitaxially grown. For example, the semiconductor layer sequence has been epitaxially deposited on the growth substrate, for example by means of metal organic vapor phase epitaxy, abbreviated as MOVPE, or metal organic chemical vapor deposition, abbreviated as MOCVD, or by means of molecular beam epitaxy, abbreviated as MBE. Preferably, the semiconductor layer sequence has been grown as a single piece.

Alternatively, the semiconductor layer sequence may have been detached from the growth substrate and transferred to the substrate. In this case, the substrate is different from the growth substrate.

According to at least one embodiment of the method or its embodiment described above, the semiconductor layer sequence is etched so that the semiconductor layer sequence comprises the shape of a generalized cylinder or a frustum with a main axis perpendicular to a main extension plane of the semiconductor layer sequence. For example, a main surface of the semiconductor layer sequence, which is parallel to the main extension plane of the semiconductor layer sequence and forms an outwardly exposed surface of the semiconductor layer sequence, is partially covered with a mask. Preferably, the mask comprises the shape of a circular disk or a regular polygon, such as a hexagon or an octagon, when viewed in plan view of the main surface of the semiconductor layer sequence. Subsequently, the semiconductor layer sequence is etched so that non-masked regions of the semiconductor layer sequence are removed. For example, a dry chemical etching method, such as plasma etching, or a wet chemical etching method, such as etching with KOH, is used.

According to at least one embodiment of the method or embodiments thereof described above, a core region and an edge region of the semiconductor layer sequence are formed, wherein the core region is bounded by the edge region in directions perpendicular to the main axis. For this purpose, a refractive index of the semiconductor layer sequence is changed region by region. In particular, the refractive index of the semiconductor layer sequence is deliberately reduced in the edge region or the refractive index of the semiconductor layer sequence is deliberately increased in the core region. In particular, the semiconductor layer sequence in the edge region comprises a lower refractive index than in the core region. Preferably, the edge region and the core region are directly adjacent to each other, so that the edge region and the core region form an interface.

Advantageously, by integrally forming the semiconductor layer sequence, then etching and subsequently forming the core region and the edge region, a semiconductor laser diode can be produced in which a ring mode runs at an interface between the core region and the edge region.

According to at least one embodiment of the method or embodiments thereof described above, the refractive index of the semiconductor layer sequence in the edge region is reduced by introducing foreign atoms by means of diffusion. A similar method is also known, for example, as “quantum well intermixing”. For example, aluminum atoms are introduced as impurity atoms in the edge region of the semiconductor layer sequence. For example, in this method step, the semiconductor layer sequence is heated to a temperature between 800° C. and 1000° C., inclusive, so that the impurity atoms can diffuse into the semiconductor layer sequence. Preferably, the diffusion of the impurity atoms into the semiconductor layer sequence takes place under an inert gas atmosphere. In particular, argon is used as the inert gas.

Further preferably, the semiconductor layer sequence is dielectrically encapsulated during the diffusion of impurity atoms. For example, silicon dioxide or silicon nitride is applied to the semiconductor layer sequence for this purpose, so that a semiconductor material of the semiconductor layer sequence is protected from the high temperatures during the diffusion of the impurity atoms. Advantageously, the refractive index in the edge region can be reduced particularly easily by introducing impurity atoms.

According to at least one embodiment of the method or embodiments thereof described above, the refractive index of the semiconductor layer sequence in the core region is increased by applying a dielectric element in places to a main surface of the semiconductor layer sequence. For example, the dielectric element is deposited. In particular, the dielectric element is applied by vapor deposition. For example, the dielectric element comprises silicon dioxide (SiO2) and/or silicon nitride (SiN). By applying the dielectric element, mechanical strains are induced in the semiconductor layer sequence. As a result of the mechanical strains, the refractive index of the semiconductor layer sequence increases in the core region. Advantageously, the refractive index of the semiconductor layer sequence in the core region can thus be increased by applying the dielectric element without having to expose the semiconductor material of the semiconductor layer sequence to external influences that could damage the material.

According to at least one embodiment of the method or embodiments thereof described above, a contact structure is arranged on a surface of the dielectric element facing away from the main surface. In this case, the contact structure is arranged such that the contact structure penetrates the dielectric element in places and the contact structure is in direct contact with the semiconductor layer sequence in places. In intended operation, the semiconductor layer sequence is supplied with current in particular by the contact structure. For example, the contact structure comprises one or more metals, such as titanium, platinum and/or gold. For example, the contact structure is applied by sputtering.

In particular, the dielectric element is structured prior to applying the contact structure. For example, the dielectric element is structured in a lithographically defined etching process. Preferably, the application of the contact structure to the semiconductor layer sequence changes the refractive index of the semiconductor layer sequence at these locations only insignificantly compared to the refractive index of the semiconductor layer sequence covered by the dielectric element.

According to at least one embodiment of the method or embodiments thereof described above, an output coupling structure is formed in the edge region. For this purpose, the refractive index of the semiconductor layer sequence in the region of the output coupling structure is increased relative to the edge region surrounding the output coupling structure. For example, the diffusion of foreign atoms is deliberately avoided in the region of the output coupling structure. Advantageously, in the region of the output coupling structure, a refractive index difference of the semiconductor layer sequence between the edge region and the core region is smaller than in the remaining edge region or disappears completely, so that in this region radiation guided along the interface between the core region and the edge region can leave the semiconductor layer sequence.

According to at least one embodiment of the method or embodiments thereof described above, a further dielectric element is arranged on the semiconductor layer sequence in the region of the output coupling structure. For example, the further dielectric element is applied with the same methods as the dielectric element covering the core region and comprises the same materials. Advantageously, the refractive index in the region of the output coupling structure can be further increased by applying a further dielectric element, so that radiation traveling along the interface between the core region and the edge region preferably leaves the semiconductor layer sequence in the region of the output coupling structure.

According to at least one embodiment of the method or embodiments thereof described above, a passivation layer is arranged on an outer surface of the semiconductor layer sequence which extends transversely, in particular perpendicularly, to the main surface. The outer surface is in particular a lateral surface of the semiconductor layer sequence. For example, the passivation layer is deposited on the outer surface. For example, the passivation layer comprises a II-VI compound semiconductor material, such as ZnSe. Preferably, the passivation layer is transparent to electromagnetic radiation generated in the active zone during intended operation. Advantageously, by applying a passivation layer to the outer surface of the semiconductor layer sequence, the semiconductor layer sequence can be particularly well protected against environmental influences.

Further advantages and advantageous embodiments and further developments of the semiconductor laser diode and the method are explained in connection with the following exemplary embodiments shown in connection with the schematic drawings. Elements which are identical, of the same kind and have the same effect are provided with the same reference signs in the figures. The figures and the proportions of the elements shown in the figures with respect to one another are not to be regarded as fundamentally to scale. Rather, individual elements may be shown exaggeratedly large for better illustration and/or for better comprehensibility.

### BRIEF DESCRIPTION OF THE DRAWINGS

In the figures:

FIGS. 1 to 7 and 9 to 12 show exemplary embodiments of the semiconductor laser diode in various views.

FIGS. 8A to 8D show various process stages of a method for producing a semiconductor laser diode according to an exemplary embodiment.

### DETAILED DESCRIPTION

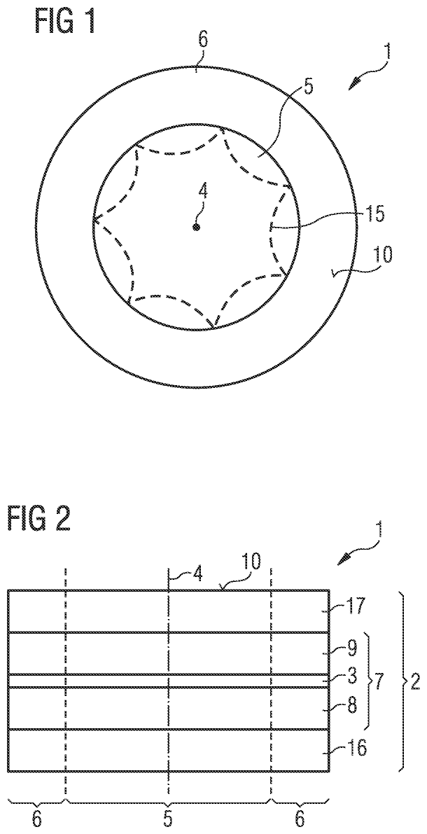

FIG. 1 shows a semiconductor laser diode 1 according to a first exemplary embodiment in a plan view of a main surface 10 of the semiconductor layer sequence 2. The main surface 10 extends parallel to a main extension plane of the semiconductor layer sequence 2 and perpendicular to a main axis 4 of the semiconductor layer sequence 2, which comprises the shape of a straight circular cylinder. The main axis 4 is in particular a rotational symmetry axis of the semiconductor layer sequence 2.

The semiconductor layer sequence 2 comprises a core region 5 around the main axis 4 and, viewed from the main axis 4, an edge region 6 surrounding the core region 5. The edge region 6 and the core region 5 are directly adjacent to each other and comprise an interface with each other. In particular, the core region 5 is completely enclosed by the edge region 6 in directions perpendicular to the main axis 4. In a plan view of the main surface 10, the core region 5 comprises the shape of a circular disk. In the same view, the edge region 6 comprises the shape of a circular ring. In particular, the core region 5 and the edge region 6 each comprise an axis of rotational symmetry that coincides with the main axis 4 of the semiconductor layer sequence 2.

The semiconductor layer sequence 2 comprises a lower refractive index in the edge region 6 than in the core region 5. For example, a refractive index difference of the semiconductor layer sequence 2 between the edge region 6 and the core region 5 is 1×10⁻³. Due to the refractive index difference between the core region 5 and the edge region 6, electromagnetic radiation 15, indicated here and below as a dashed line for illustration, generated in the active zone 3 of the semiconductor layer sequence 2 propagates at the interface between the core region 5 and the edge region 6 in the semiconductor layer sequence 2. In particular, due to the refractive index difference, the electromagnetic radiation 15 is reflected at the interface by means of total internal internal reflection. Preferably, a ring mode of the electromagnetic radiation 15 is thus formed within the core region. Preferably, the core region 5 comprises, in plan view, a diameter of at least 1 μm and at most 200 μm, in particular of at least 5 μm and at most 50 μm, whereby in particular the condition for total reflection is fulfilled. The edge region 6 comprises a width, measured perpendicular to the main axis 4, which is between 100 nm and 10 μm inclusive. Preferably, the width is such that an evalescent wave formed in the edge region 6 due to total internal reflection at the interface between the core region 5 and the edge region 6 is not transmitted through the edge region 6.

In FIG. 2 the semiconductor laser diode of FIG. 1 is shown in a schematic sectional view. A sectional plane runs parallel to the main axis 4 and includes the main axis 4. The semiconductor layer sequence 2 comprises a first cover layer 16, a second cover layer 17 and a central zone 7, wherein the central zone 7 is arranged between the first 16 and the second 17 cover layer. The central zone 7 comprises a first waveguide layer 8, a second waveguide layer 9, and an active zone 3 arranged between the first waveguide layer 8 and the second waveguide layer 9. In the active zone 3, electromagnetic radiation 15 in the visible wavelength range or in the UV range or preferably in the IR range is generated during intended operation. In the present case, the semiconductor layer sequence 2 is based on an arsenide compound semiconductor material, such as InAlGaAs. In intended operation, electromagnetic radiation 15 with a peak wavelength of 910 nm, for example, is generated in the active zone 3. The peak wavelength is the wavelength at which the electromagnetic radiation generated in the active zone comprises its global intensity maximum. For example, the first cover layer 16 and the first waveguide layer 8 are n-doped. The second cover layer 17 and the second waveguide layer 9 are then p-doped. Alternatively, the doping can be the other way around. Preferably, the central zone 7 comprises a refractive index different from those of the first and second cover layers 16, 17. Preferably, electromagnetic radiation 15 generated in the active zone 3 propagates only in the central zone 7.

For example, the semiconductor layer sequence 2, in particular the central zone 7, comprises a refractive index of 3.5 in the core region 5. For example, the refractive index is an average refractive index. Preferably, the refractive index is specified for radiation 15 generated in the active zone 3. In particular, the refractive index is specified with reference to the peak wavelength. In the present case, therefore, for electromagnetic radiation 15 with a wavelength of 910 nm. The central zone 7 comprises a refractive index of 3.499 in the edge region 6. For example, the refractive index is an average refractive index.

In the present case, impurity atoms are introduced in the edge region 6 of the central zone 7. The impurity atoms are, for example, elements of group II, preferably aluminum. In particular, the impurity atoms change a band gap of the central zone 7 in the edge region 6. As a result, the refractive index of the central zone 7 in the edge region 6 is reduced. A concentration of impurity atoms in the edge region 6 of the central zone 7 is preferably between 1×10¹⁷ and 1×10²⁰ cm⁻³.

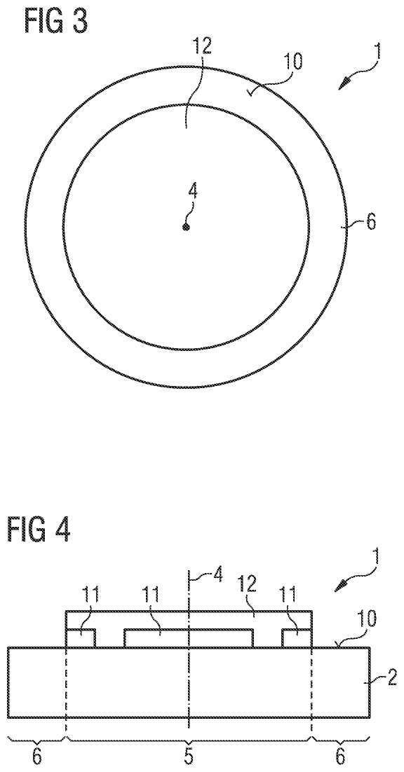

The semiconductor laser diode 1 according to the exemplary embodiment of FIG. 3 shows essentially the same features as the semiconductor laser diode 1 according to FIG. 1. In contrast to the semiconductor laser diode of FIG. 1, here the core region 5 is covered by a contact structure 12 in plan view.

The semiconductor laser diode 1 of FIG. 3 is shown in FIG. 4 in a schematic sectional view. A sectional plane runs through the main axis 4. A dielectric element 11 is arranged on a main surface 10 of the semiconductor layer sequence 2. The dielectric element 11 covers the core region 5 of the semiconductor layer sequence 2 in places. In particular, the dielectric element 11 covers a major part of the main surface 10 in the core region 5. A contact structure 12 is arranged on a surface of the dielectric element 11 facing away from the main surface 10. The dielectric element 11 has been removed in places, so that the dielectric element 11 has a present two-part configuration. A first part of the optical element 11 comprises the shape of a circular disk in plan view. In particular, the main axis runs through this first part. The second part of the dielectric element 11 comprises the shape of a circular ring in plan view, which surrounds the first part of the dielectric element 11 in all directions perpendicular to the main axis 4. In regions formed between the first region and the second region of the dielectric element 11, the contact structure 12 penetrates the dielectric element 11. In these regions, the contact structure is in direct contact with the semiconductor layer sequence 2. Preferably, the contact structure 12 is in contact with the semiconductor layer sequence 2 exclusively in the core region 5.

For example, the dielectric element 11 was deposited on the main surface 10, in particular by means of vapor deposition, and subsequently structured in a lithographically defined etching process. Subsequently, for example, the contact structure 12 was sputtered onto the dielectric element 11.

The dielectric element 11 comprises, for example, an oxide, such as silicon dioxide (SiO2), or a nitride, such as silicon nitride (SiN). The contact structure 12 is formed, for example, from a metal, such as gold, platinum, or titanium, or is formed from a mixture of these metals.

Mechanical strains are induced in the semiconductor layer sequence 2 by the dielectric element 11. Preferably, the mechanical strains extend over the entire thickness of the semiconductor layer sequence 2 measured parallel to the main axis 4. Due to the mechanical strains, the refractive index of the semiconductor layer sequence 2 in the core region 5 is increased compared to the refractive index of the semiconductor layer sequence 2 in the edge region 6. For example, a refractive index difference of the semiconductor layer sequence 2 between the core region 5 and the edge region 6 is at least 1×10⁻³.

In intended operation, the semiconductor layer sequence 2 is supplied with current in particular by the contact structure 12. Preferably, the contact structure 12 is in direct contact with a semiconductor layer of the semiconductor layer sequence which is p-doped. Thus, the contact structure 12 is preferably a p-contact structure.

The semiconductor laser diode 1 of FIG. 5 shows essentially the same features as FIG. 1 with the difference that a contact structure 12 is arranged at the main surface 10. The contact structure 12 is preferably a p-contact structure 12 which comprises an axis of rotational symmetry which coincides with the main axis 4 of the semiconductor layer sequence 2. The p-contact structure 12 is only in direct contact with the semiconductor layer sequence 2 in the core region 5. In intended operation, the semiconductor layer sequence 2 is supplied with current via the contact structure 12. Due to the direct contact between the semiconductor layer sequence 2 and the contact structure exclusively in the core region 5, electromagnetic radiation is preferably generated exclusively in the core region 5.

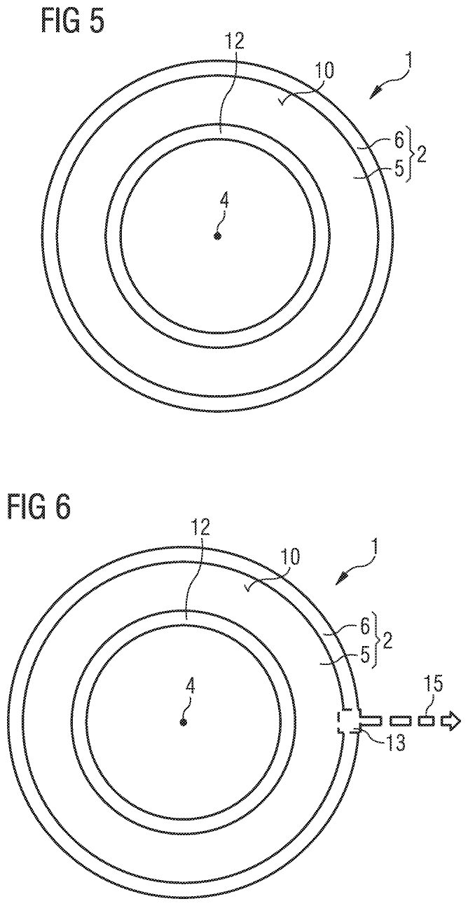

The semiconductor laser diode 1 of FIG. 6 shows essentially all features of the semiconductor laser diode of FIG. 5 with the difference that an output coupling structure 13 is formed in the edge region 6. For example, in the region of the output coupling structure 13, diffusion of impurity atoms has been prevented. In particular, the semiconductor layer sequence 2 comprises the same refractive index in the region of the output coupling structure 13 as in the core region 5. Since there is thus no difference in refractive index between the core region 5 and the edge region 6 in the region of the output coupling structure 13, the condition for total internal reflection is not fulfilled here. Electromagnetic radiation 15 can therefore leave the semiconductor laser diode 1 in the region of the output coupling structure 13 perpendicular to the main axis 4.

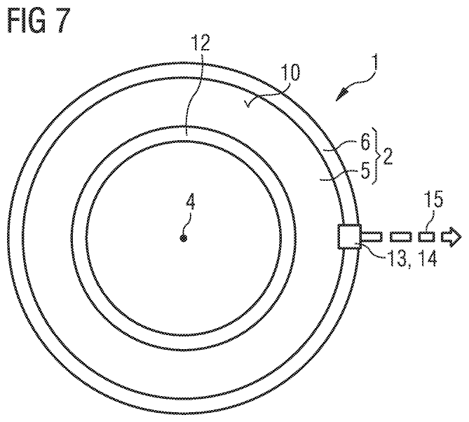

The semiconductor laser diode 1 according to the exemplary embodiment of FIG. 7 comprises essentially the same features as the semiconductor laser diode of FIG. 6 with the difference that a further dielectric element 14 is arranged on the main surface 10 in the region of the output coupling structure 13. The further dielectric element 14 induces mechanical strains in the semiconductor layer sequence 2 in the region of the output coupling structure 13, whereby the refractive index in this region is increased compared to the surrounding edge region 6. For example, in the region of the output coupling structure 13, the refractive index of the semiconductor layer sequence 2 is increased above the value of the semiconductor layer sequence 2 in the core region 5. Therefore, the output of electromagnetic radiation 15 from the core region 5 is increased in the region of the output coupling structure 13.

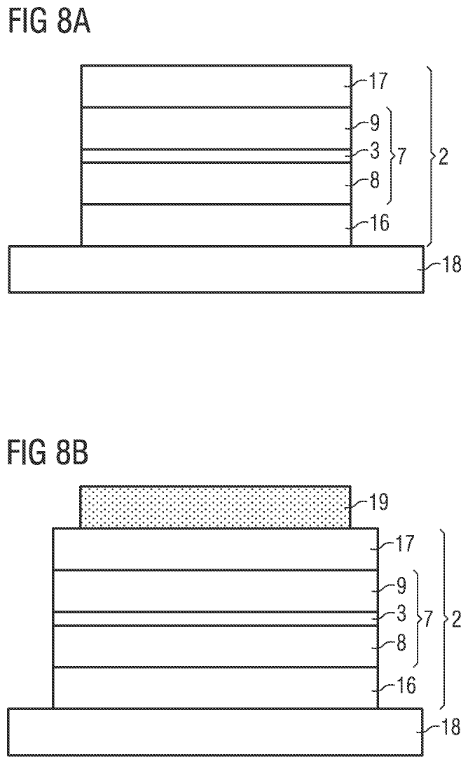

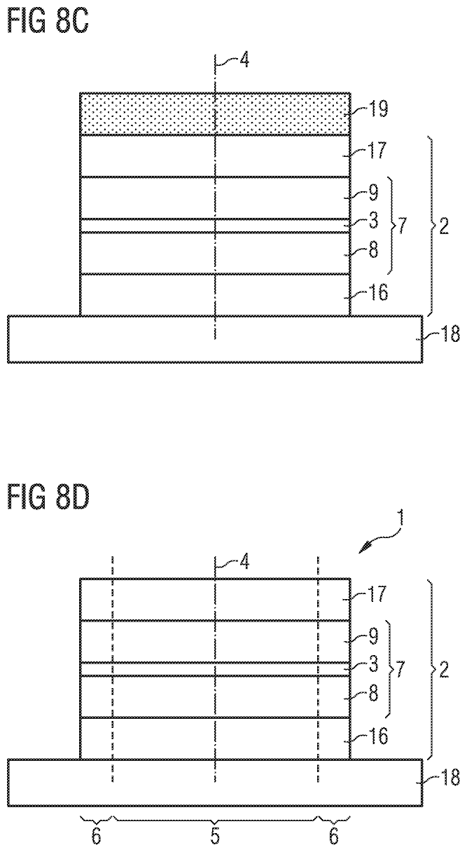

In the method according to the exemplary embodiment of FIGS. 8A to 8D, a semiconductor layer sequence 2 is first provided on a substrate 18 (FIG. 8A). In particular, this method is used to produce a semiconductor laser diode 1 according to one of the exemplary embodiments explained above. The semiconductor layer sequence 2 comprises a first cover layer 16, a second cover layer 17 and a central zone 7 between these two layers. The central zone 7 comprises a first waveguide layer 8, a second waveguide layer 9, and an active zone 3 arranged therebetween. The substrate 18 is, for example, the growth substrate of the semiconductor layer sequence 2. In particular, the semiconductor layer sequence 2 has been grown on the substrate 18 in one piece.

In a next step, a mask 19 is applied to a surface of the semiconductor layer sequence 2 opposite to the substrate 18 (FIG. 8B). For example, the mask 19 is deposited on the semiconductor layer sequence 2. The mask 19 is, for example, a hard mask.

In a further step of the method, unmasked regions of the semiconductor layer sequence 2 are etched (FIG. 8C). In this process, semiconductor material of the semiconductor layer sequence 2 is removed in regions which are not covered by the hard mask 19. After etching, the semiconductor layer sequence 2 comprises a cylindrical shape. In particular, the semiconductor layer sequence 2 comprises a main axis 4. The main axis 4 runs perpendicular to the main extension plane of the semiconductor layer sequence 2, in particular perpendicular to the main extension plane of the active zone 3.

In a further method step, a core region 5 and an edge region 6 are formed (FIG. 8D). Previously, the hard mask 19 was removed. The edge region 6 is formed, for example, by introducing foreign atoms into the semiconductor layer sequence 2. For example, a refractive index of the semiconductor layer sequence 2 is reduced in the edge region. The impurity atoms are introduced into the semiconductor layer sequence 2 by diffusion, for example. For example, aluminum is diffused into the semiconductor layer sequence 2 based on a III-V compound semiconductor material. In particular, the impurity atoms change a band gap of the semiconductor layer sequence 2 in the edge region 6. As a result, the refractive index of the semiconductor layer sequence 2 is reduced in the edge region 6. In particular, by forming the core region 5 and the edge region 6, a finished semiconductor laser diode 1 is formed.

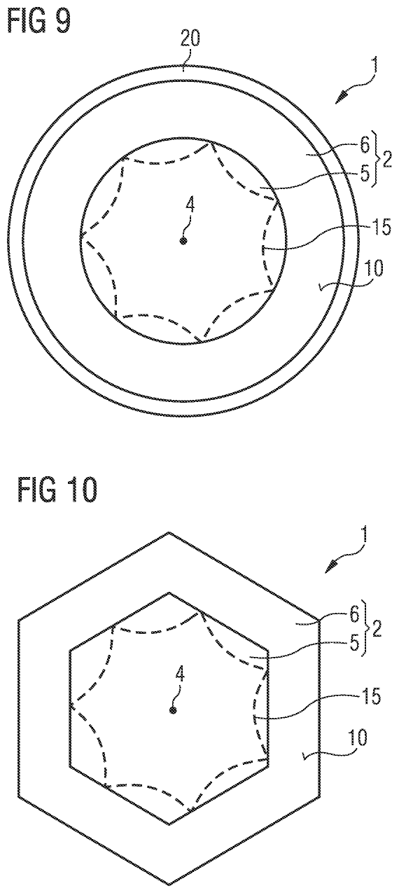

In contrast to the semiconductor laser diode 1 of FIG. 1, the semiconductor laser diode 1 according to the exemplary embodiment of FIG. 9 comprises an additional passivation layer 20. The passivation layer 20 is arranged on an outer surface of the semiconductor layer sequence 2, in particular of the edge region 6. The outer surface extends transversely, in particular perpendicularly, to the main surface 10 of the semiconductor layer sequence 2. The outer surface forms a lateral surface of the cylindrical semiconductor layer sequence 2. The passivation layer 20 completely covers the outer surface. The passivation layer 20 is formed, for example, with a II-VI compound semiconductor material, such as ZnSe. For example, the passivation layer 20 was applied after forming the edge region 6 and core region 5. For example, the passivation layer 20 was vapor deposited or deposited on the outer surface.

The exemplary embodiment of the semiconductor laser diode 1 according to FIG. 10 differs from the exemplary embodiment of FIG. 1 in that the semiconductor layer sequence 2 comprises the shape of a prism, in particular a straight prism. In the present plan view of the main surface 10, it can be seen that the prism comprises a base surface in the shape of a regular hexagon. For example, the semiconductor layer sequence 2 is based on GaN. In this case, advantageously, a semiconductor layer sequence 2 with the present geometrical shape can be produced particularly well.

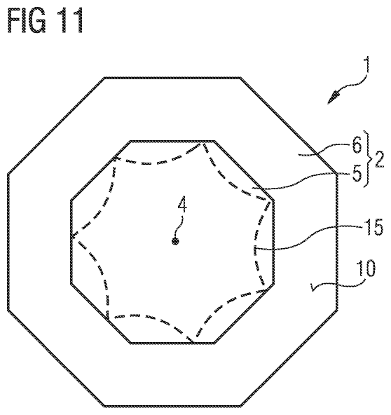

The semiconductor laser diode 1 of FIG. 11 comprises essentially the same features as the semiconductor laser diode 1 of FIG. 10 with the difference that the base surface of the prism comprises the shape of a regular octagon.

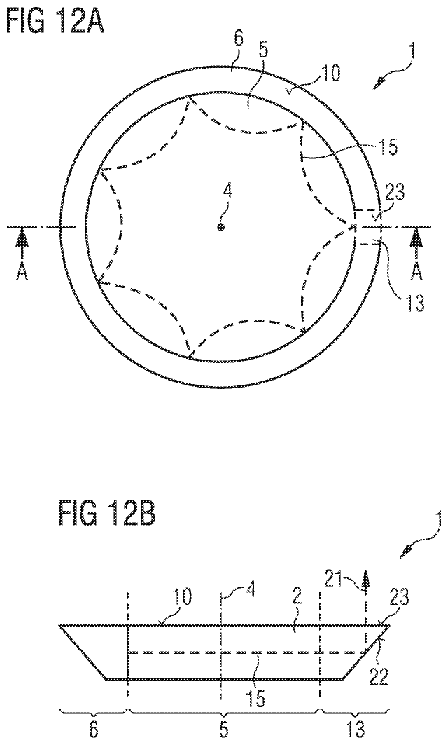

The exemplary embodiment of the semiconductor laser diode 1 of FIGS. 12A and 12B differs from the exemplary embodiment of FIG. 1 inter alia in that the semiconductor layer sequence 2 comprises the shape of a frustum. FIG. 12A shows a plan view of the main surface 10 of the semiconductor layer sequence 2. FIG. 12B shows a section through the semiconductor layer sequence 2 according to FIG. 12A perpendicular to the drawing plane along the line A-A drawn therein.

The semiconductor laser diode 1 according to this exemplary embodiment comprises an output coupling structure 13 which essentially corresponds to the output coupling structure 13 explained in connection with FIG. 6. In particular, no total internal reflection of the radiation 15 occurs in the region of the output coupling structure 13 at the interface between the edge region 6 and the core region 5. Thus, radiation can penetrate into the edge region 6 in the region of the output coupling structure 13.

Side surfaces 22 of the semiconductor layer sequence 2 enclose an angle of, for example, 45° with the main surface 10 (see FIG. 12B). In the region of the output coupling structure 13, total internal reflection occurs at the side surface 22 of the semiconductor layer sequence 2 during operation. Due to the inclined side surface 22, the radiation 15 is reflected in the direction of the main surface 10 of the semiconductor layer sequence 2 during operation. In operation, the reflected radiation 15 exits the semiconductor layer sequence 2 through an output coupling surface 23. The output coupling surface 23 is a part of the main surface 10 (see FIG. 12A).

A main emission direction 21 of the radiation emitted from the semiconductor laser diode 1 in operation is parallel to the main axis 4.

The invention is not limited to the exemplary embodiments by the description thereof. Rather, the invention encompasses any new feature as well as any combination of features, which particularly includes any combination of features in the patent claims, even if that feature or combination itself is not explicitly specified in the patent claims or exemplary embodiments.

1. A semiconductor laser diode comprising a semiconductor layer sequence with an active zone, wherein
the semiconductor layer sequence comprises a shape of a generalized cylinder or a frustum,
a main axis of the semiconductor layer sequence is perpendicular to a main extension plane of the semiconductor layer sequence,
the semiconductor layer sequence comprises a core region and an edge region directly adjacent to the core region,
the main axis passes through the core region,
the edge region bounds the core region in directions perpendicular to the main axis,
the semiconductor layer sequence comprises a larger refractive index in the core region than in the edge region,
on a main surface of the semiconductor layer sequence a dielectric element is arranged,
the dielectric element covers the core region in places,
the edge region is free of the dielectric element, and
the dielectric element causes mechanical strains in the semiconductor layer sequence, which changes the refractive index of the semiconductor layer sequence.

2. The semiconductor laser diode according to claim 1, wherein the core region and the edge region are based on the same semiconductor material system.

3. The semiconductor laser diode according to claim 1, wherein the semiconductor layer sequence comprises the shape of a straight circular cylinder.

4. The semiconductor laser diode according to claim 1, wherein the semiconductor layer sequence comprises the shape of a prism.

5. The semiconductor laser diode according to claim 1, wherein impurity atoms are introduced in the semiconductor layer sequence in the edge region.

6. The semiconductor laser diode according to claim 5, wherein the semiconductor layer sequence comprises a central zone which is at least partially located within the edge region, wherein
the central zone comprises the active zone, a first waveguide layer and a second waveguide layer
the active zone is arranged between the first and the second waveguide layers, and
impurity atoms are introduced into regions of the central zone that are within the edge region.

7. (canceled)

8. The semiconductor laser diode according to claim 1, wherein a contact structure is arranged on a surface of the dielectric element facing away from the main surface (10), wherein
the contact structure penetrates the dielectric element in places, and
the contact structure is in direct contact with the semiconductor layer sequence in places.

9. The semiconductor laser diode according to claim 1, wherein
the edge region comprises an output coupling structure, wherein
the semiconductor layer sequence comprises a higher refractive index in the region of the output coupling structure than in the edge region surrounding the output coupling structure.

10. The semiconductor laser diode according to claim 9, wherein a main emission direction of radiation generated in operation is parallel to the main axis.

11. The semiconductor laser diode according to claim 9,
wherein the semiconductor layer sequence (2) is in direct contact with a further dielectric element (14) in the region of the output coupling structure (13).

12. The semiconductor laser diode according to claim 1, wherein
the semiconductor layer sequence is based on an AlₙIn₁₋ₙ₋ₘGaₘAs material system, an AlₙIn₁₋ₙ₋ₘGaₘN material system or an AlₙIn₁₋ₙ₋ₘGaₘP material system, wherein 0≤n≤1, 0≤m≤1 and m+n≤1,
a refractive index difference between the semiconductor layer sequence in the core region and the edge region is at least 0.1% and at most 1%.

13. A method for producing a semiconductor laser diode comprising:
providing a semiconductor layer sequence with an active zone;
etching the semiconductor layer sequence so that the semiconductor layer sequence comprises a shape of a generalized cylinder or a frustum with a main axis perpendicular to a main extension plane of the semiconductor layer sequence;
forming a core region and an edge region by changing a refractive index of the semiconductor layer sequence region by region, wherein the core region is bounded by the edge region in directions perpendicular to the main axis,
wherein
the refractive index of the semiconductor layer sequence in the core region is increased by applying a dielectric element in places to a main surface of the semiconductor layer sequence.

14. The method according to claim 13,
wherein the refractive index of the semiconductor layer sequence in the edge region is reduced by introducing foreign atoms by means of diffusion.

15. (canceled)

16. The method according to claim 13,
wherein a contact structure (12) is arranged on a surface of the dielectric element (11) facing away from the main surface (10) in such a way that
the contact structure (12) penetrates the dielectric element (11) in places, and
the contact structure (12) is in direct contact with the semiconductor layer sequence (2) in places.

17. The method according to claim 13,
wherein an output coupling structure is formed in the edge region by increasing the refractive index of the semiconductor layer sequence in the region of the output coupling structure relative to the edge region surrounding the output coupling structure.

18. The method according to claim 17, wherein a further dielectric element is arranged on the semiconductor layer sequence in the region of the output coupling structure.

19. A semiconductor laser diode comprising a semiconductor layer sequence with an active zone, wherein
the semiconductor layer sequence comprises a shape of a generalized cylinder or a frustum,
a main axis of the semiconductor layer sequence is perpendicular to a main extension plane of the semiconductor layer sequence,
the semiconductor layer sequence comprises a core region and an edge region directly adjacent to the core region,
the main axis passes through the core region,
the edge region bounds the core region in directions perpendicular to the main axis,
the semiconductor layer sequence comprises a larger refractive index in the core region than in the edge region.

20. The semiconductor laser diode according to claim 19, wherein a main emission direction of radiation generated in operation is parallel to the main axis.
